(19) United States
(12) Patent Application Publication
(10) Pub. No.: US 2003/0098490 A1
(43) Pub. Date: May 29, 2003

(54) Wide bandwidth high efficiency photodiode

(76) Inventors: Andrew Gomperz Dentai, Moutain View, CA (US); Hong Ji, Norristown, PA (US); Thomas Gordon Beck Mason, Bethlehem, PA (US); Ola Sjolund, Macungie, PA (US); P. Douglas Yoder, New Providence, NJ (US)

Correspondence Address: Wendy W. Koba, Esq., P.O. Box 556, Springtown, PA, 18081-0556, US

(21) Appl. No.: 09/994,155

(22) Filed: Nov. 26, 2001

(51) Int. Cl. H01L 31/00

(52) U.S. Cl. 257/444

(57) ABSTRACT

The present invention is directed toward an edge detecting photodiode that includes a waveguide comprising a p-doped InP cladding layer, an n-doped InP cladding layer, a p-side waveguide layer, an n-side waveguide layer, and an InGaAs absorption layer therebetween, in which the absorption layer is doped to have an absorption region and a depletion region that, when under bias, will overlap by an amount sufficient to substantially balance the transit time of positive and negative charged carriers across the waveguide. The photodiode is preferably formed on an InP substrate. The photodiode preferably has a planar polymer layer in contact with the InP substrate. The polymer layer also preferably has a ridge formed therein for the photodiode waveguide. The polymer layer may have a coplanar transmission line deposited thereon, and a pair of metal-insulator-metal (“MIM”) capacitors may be incorporated into the coplanar transmission line.

### BACKGROUND OF THE INVENTION

1. Field of the Invention

The present invention relates to a photodiode. More particularly, the present invention relates to a high efficiency wide bandwidth waveguide photodiode. Even more particularly, the present invention involves an edge illuminating waveguide heterojunction photodiode with special dopant distribution.

2. Description of the Prior Art

Conventional surface illuminated photodiodes suffer from a significant disadvantage in that there is a fundamental tradeoff between the transit time and absorption depth within the semiconductor. This typically imposes a sever limitation on the internal quantum efficiency of these high speed photodiodes.

This problem has been addressed in the prior art by two primary methods. One method is to use a resonant cavity design that trades off the optical bandwidth of the photodiode for improvements in the absorption efficiency. The other approach is to use an edge-illuminated detector employing either a beam expander on the input or a multi-mode waveguide design. Bandwidth targets are achieved by adjustments to the physical device area and/or the absorption layer thickness.

However, these approaches still result in semiconductor photodiodes with distinct disadvantages. For example, current edge illuminated designs are typically polarization dependent or have a very tight alignment tolerance for optical coupling. Moreover, the aforementioned resonant cavity designs are not able to operate over a wide wavelength range. Meeting bandwidth targets by means of adjustments to the device area or the absorption layer thickness can have a deleterious impact on other properties of the device, including responsivity and sensitivity to optical polarization.

Accordingly, a system is needed which will provide high quantum efficiency, lower polarization dependence, and an extremely wide bandwidth while simultaneously reducing transit time and increasing absorption depth.

### SUMMARY OF THE INVENTION

The present invention is directed toward an edge detecting photodiode having a waveguide that includes a positively doped InP cladding layer, a negatively doped InP cladding layer, and an InGaAs absorption layer therebetween, in which the absorption layer is doped to have an absorption region and the depletion region that, when under bias, will overlap each other to form an undepleted absorption region, an overlapping region, and a depleted region that substantially balance the transit time of positive and negative charge carriers across the waveguide. The photodiode preferably has an InP substrate and a planar polymer layer in contact with the InP substrate. The polymer layer preferably has a ridge formed therein for the photodiode waveguide and is preferably formed from Benzocyclobutene (“BCB”). The polymer layer may have a coplanar transmission line deposited thereon, and a pair of metal-insulator-metal (“MIM”) capacitors may be incorporated into the coplanar transmission line.

### BRIEF DESCRIPTION OF THE DRAWINGS

FIG. 1 is a top view of a photodetector containing a waveguide photodiode in accordance with the preferred embodiment of the present invention.

FIG. 2(a) is a cross-section along lines A-A of FIG. 1.

FIG. 2(b) is an exploded view of the cross-section of FIG. 2(a).

FIG. 3 is a diagram illustrating the charge transport characteristics of the disjoint absorption/depletion regions of the preferred embodiment of the present invention.

FIG. 4 is a three-dimensional chart illustrating the optimization of the disjoint absorption/depletion regions of the preferred embodiment of the present invention for the proper weighting of transit time and RC considerations.

### DETAILED DESCRIPTION OF THE PREFERRED EMBODIMENT

The present invention will be understood more fully from the detailed description given below and from the accompanying drawings of preferred embodiments of the invention, which, however, should not be taken to limit the invention to a specific embodiment, but are for explanation and understanding only.

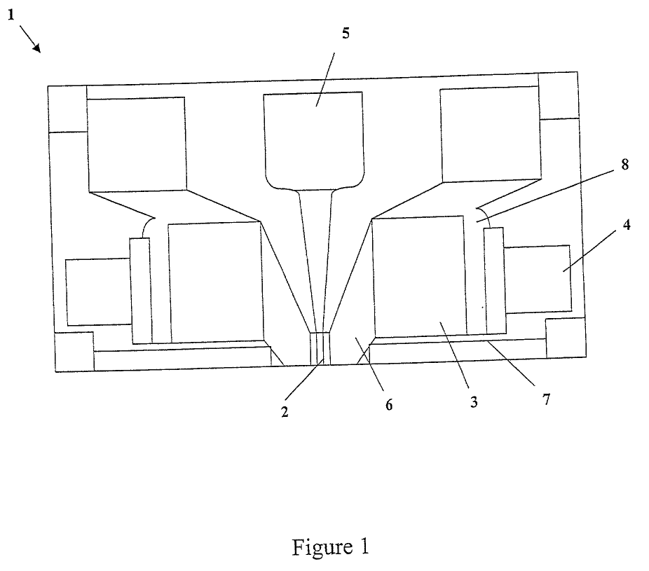

FIG. 1 is a top view of a preferred embodiment of the waveguide photodetector of the present invention. Detector (1) includes photodiode (2), MIM capacitors (3), DC bias (4), and RF contacts (5), which are preferably arranged and interconnected in a conventional manner as shown.

Detector (1) is typically formed of a semiconductor substrate material, such as silicon, or, preferably, Indium Phosphide (InP), onto which the remaining components are mounted using conventional photolithography and vapor deposition processes. Photodiode (2) is preferably an improved heterojunction PIN photodiode, as discussed in more detail below. In the preferred embodiment of the invention photodiode (2) is approximately 4 μm wide by 20 μm long having contacts (6) that form a coplanar microwave transmission line across detector (1), in a conventional matter. MIM capacitors (3) are included to isolate RF grounds (7) from DC bias path (8). The operation of MIM capacitors, RF grounds, and DC bias in connection with photodiodes is well known to those of ordinary skill in the art and will not be elaborated upon here.

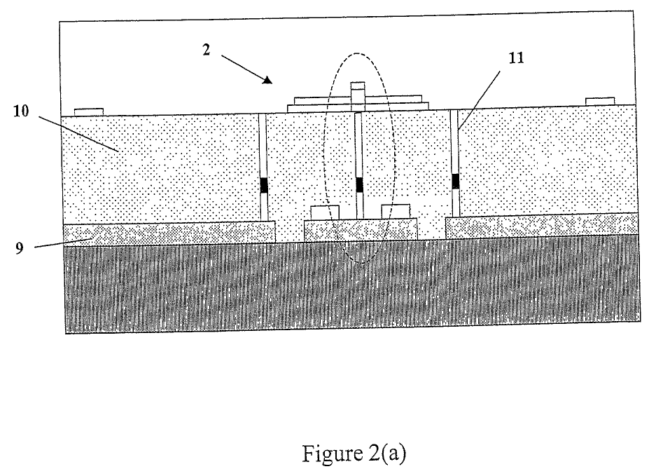

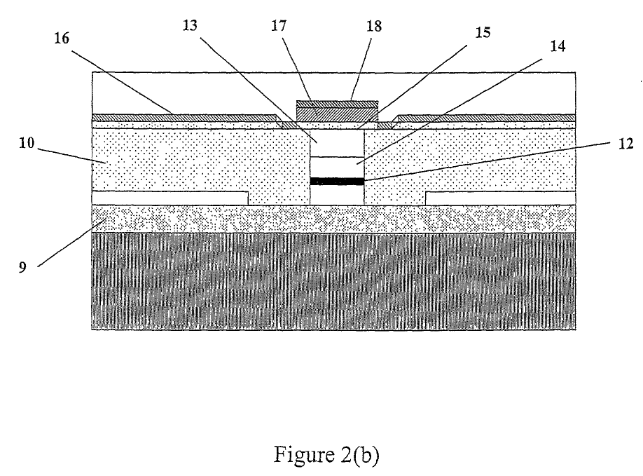

FIG. 2 illustrates a cross-section of detector (1), and specifically the structure of photodiode (2). As noted above, a base substrate, such as InP, is used as a mount for the detector components. An n-doped InP cladding layer (9) is preferably deposited thereon using conventional means. A polymer layer (10) is used to planarize the surface of the detectors and to encapsulate the sidewalls for photodiode (2) as shown. In the preferred embodiment of the invention, polymer layer (10) comprises benzocyclobutene (“BCB”), but is not limited thereto. The polymer layer (10) is preferably 4 μm deep, having a 4 μm deep ridge formed therein for the deposit and growth of the waveguide of the present invention.

This construction has the significant advantage that polymer layer (10) act as a passivation layer for the sidewalls of the detector. The InP substrate substantially reduces parasitic capacitance in photodiode (2) due to its semi-insulating properties. Moreover, the use of coplanar topside contacts on polymer layer (10) provides the significant advantage that photodiode (2) can be flip chip mounted onto a coplanar transmission line (6), to substantially eliminate the parasitic inductance associated with conventional wire bond interconnects that can, in turn, limit the device bandwidth. Alignment features (11) are also incorporated into detector (1) to allow for proper alignment of the detector with the transmitting waveguide.

A more detailed view of the waveguide design of the preferred embodiment of the invention is shown in FIG. 2(b). As shown in FIG. 2(b), an Indium Gallium Arsenide (“InGaAs”) absorption layer (12) is deposited between InGaAsP waveguide layers (14) on n-doped InP cladding layer (9). A p-doped InP cladding layer (13) is then deposited upon the absorption layer.

While the thickness of each of the cladding layers, waveguide layers, and the p-doped waveguide layer are not particularly limited, it is preferred that n-InP cladding layer (9) is approximately 1 μm in thickness, and the p-doped cladding layer (13) is 1.5 μm in thickness. The InGaAs absorption layer is preferably approximately 0.4 μm (4,000 Å) in thickness, having the characteristics described in more detail below. Each of the InGaAsP waveguide layers is preferably 1.1 μm in thickness, although not limited thereto.

The preferred embodiment of the invention thereby achieves a large alignment tolerance while also achieving polarization independence and a high coupling efficiency to the detector.

The use of an InGaAs based heterojunction in the manner of the present invention provides significant advantages over conventional silicon or gallium based photodiodes. Hetero-junction diodes enable waveguide type photodetectors, which is not easily achieved in a standard Si homo-junction device. While the present invention is readily applicable to the GaAs material system, the wavelength range for InP based devices (using an InGaAs absorber) such as the present invention, is different from the wavelength range of GaAs based devices (using either InGaAs or GaAs as the absorbing material). For example, GaAs based devices can be used up to ˜1 μm wavelength, and Si based devices will reach ˜1.1 μm, while InP based devices will covers wavelengths up to greater than 1.6 μm. The present invention is particularly advantageous because modern telecommunications system typically use wavelengths around 1.3 and 1.5-1.6 μm. The operation of heterojunction photodiodes in general is, of course, well known to those skilled in the art, and will not be further elaborated upon here.

The p-doped InP cladding layer (13) is preferably capped by a p-doped InGaAs contact layer with Ohmic metal (15) deposited thereon in a conventional matter. The p-doped InGaAs contact layer is preferably approximately 2000 Å in thickness. Ohmic metal (15) may comprise any of a number of metals known to those of skill in the art, such as gold or beryllium. Capacitor dielectric (16) of MIM capacitors (3) is then deposited thereon to isolate the RF grounds, as previously mentioned. Interconnect metal (17) and a dielectric layer (18), are also included. MIM capacitors (3) provide a direct on-chip connection for the high frequency signal components, which substantially eliminates the difficulties associated with using discrete off-chip capacitors at high frequencies.

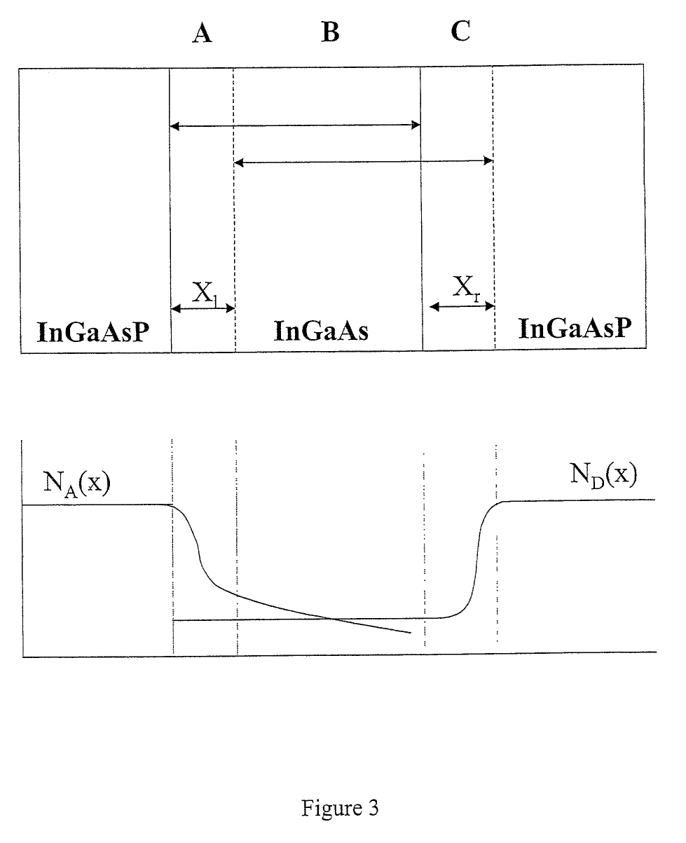

The preferred doping characteristics of the waveguide and absorption layers of the photodiode of the present invention will now be described in more detail in connection with FIG. 3. As shown in FIG. 3, and noted above, the waveguide of the present invention is preferably InGaAsP with a lightly doped InGaAs central region. In the preferred embodiment of the present invention, the absorption and depletion regions of the detector overlap each other in an overlapping region to exploit significant low and high field disparities in electron and whole drift velocities. This, in turn, substantially creates a balance between the respective charge carrier transit times. This is accomplished in the present invention by taking advantage of the high diffusivity of Zn during MOCVD growth of the detector. An optimized setback is preferably employed to insure proper penetration of the Zn tail of the acceptor distribution into the absorption region of the device.

A pull-back of the n-type dopant species, normally Si, but not limited thereto, significantly distances the main donor profile from the waveguide active region. This creates the aforementioned overlapping absorption and depletion regions under bias. As shown in FIG. 3, the positions of the p-side and n-side depletion region edges, noted by X_{L} and X_{R} respectively, are controlled primarily by the amount of Zn set-back and, the Si pull-back. These doping characteristics, in conjunction with the applied bias, determine the relative transit times of the charge carriers (electrons and holes) generated by the incident optical signal.

Within the absorption region, the undepleted tail absorption region of the acceptor profile, indicated in FIG. 3 by Region A, induces a static electric field of sufficient magnitude to promote the escape of photoexcited electrons at overshot velocities and to substantially eliminate electron-hole recombination. The remainder of the absorption region, indicated by Region B in FIG. 3, overlaps with the depletion region and electron-hole pairs that are photoexcited in this region are swept out in opposite directions by the considerable depletion field, such that holes and electrons are effectively collected at the p and n side depletion region boundaries, respectively.

The maximum electron transit distance is normally increased by an amount X_{R} during doping in the MOCVD process. In the present invention, the hole transit distance is decreased by the amount of X_{L} to create Region A, in which the holes are collected substantially immediately. Because holes are the slower carrier species, there is a difference in transit time as between holes and electrons. As a result, small positive displacements X_{L} and X_{R} are optimally sized in the present invention to effect a weighted balancing of the transit times.

The weighted balancing of charge carrier transit times, rather than their minimization, plays a dominant role in determining the bandwidth of the photodiode, of the present invention, due to the influence of the junction capacitance. The junction capacitance is inversely proportional to the depletion region thickness, and contributes a pole to the frequency response of the device. The transit time and junction capacitance thereby influence the bandwidth in compliment to each other. As a result, the actual bandwidth of the photodiode is a function of the charge transport characteristics and the complete electrical equivalent circuit.

While the width of the undepleted absorption Region A, overlapping absorption Region B, and depleted Region C are not particularly limited, it is preferred that Region A is on the order of 1000 Å, Region B is on the order of 3000 Å and Region C is on the order of 2000 Å. By properly sizing these three regions, a proper undepleted profile (represented by N_{A}(X) in FIG. 3) can be achieved. Conversely, the depletion profile (represented by N_{D}(X) in FIG. 3) is also optimized to obtain the desired capacitance and overall equivalent RC circuit for the device.

The present invention provides significant improvements over conventional PIN photodiodes and more recently developed uni-traveling-carrier (UTC) photodiodes. Conventional PIN photodiodes are dependent upon the transit of both electron and hole charge carriers. Consequently, the bandwidth of the conventional PIN photodiode is limited as a function of the junction capacitance and is inadequate for high frequency (e.g. 40 GHz) photodetector applications.

UTC photodiodes differ from conventional PIN photodiodes in that they utilize the much higher drift velocity of the electrons, operating with a short absorption region only. Consequently, UTC photodiodes have a much higher frequency response than conventional PIN photodiodes. However, because UTC photodiodes operate with a short absorption region only, their responsivity is greatly reduced as compared to conventional PIN photodiodes.

Thus, the present invention achieves the improved frequency response of UTC photodiodes, while simultaneously maintaining the greater responsivity of conventional PIN photodiodes.

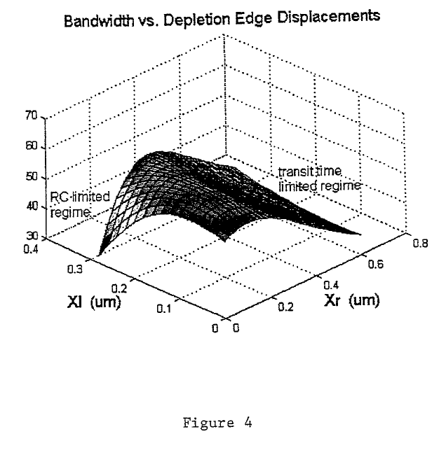

Simulations have shown that the bandwidth of the photodiode of the present invention may be maximized with respect to the junction displacements with respect to Zn setback and Si pull-back lengths. This is illustrated in the three-dimensional chart shown in FIG. 4. As shown in FIG. 4, bandwidth optimization depends primarily on control over dopant distributions and does not influence optical absorption in any significant way. Nor does it necessitate modifications to device geometry, as is required in the prior art.

In this manner, the optimized edge illuminated detector design of the present invention enables a high responsivity to be achieved at bandwidth in excess of 40 GHz with an integrated bias structure that eliminates the need for an external bias T. Moreover, the waveguide structure of the present invention makes the photodetector polarization independent and tolerant to misalignments in the optical coupling. The double topside coplanar contacts of the present invention enables the device to be flip chip mounted, substantially eliminating parasitic inductance. Moreover, proper selection of the dopant profiles allows for significant enhancement to bandwidth, while leaving other critical design considerations unaffected.

Although this invention has been described with reference to particular embodiments, it will be appreciated that many variations may be resorted to without departing from the spirit and scope of this invention.

We claim:

1. A semiconductor photodiode comprising:
a p-side waveguide layer on said semiconductor for receiving positive charge carriers;
a n-side waveguide layer on said semiconductor for receiving negative charge carriers;
an absorption layer between said p-side waveguide and said n-side waveguide layers, said absorption layer being doped to have an absorption region and a depletion region that, when under bias, will overlap each other to form an undepleted absorption region, an overlapping region, and a depleted region that substantially balance the transit time of said positive charge carriers and said negative charge carriers across said photodiode.

2. The photodiode of claim 1, wherein said semiconductor comprises InP and said absorption layer comprises InGaAs, and further comprising:
a p-doped cladding layer adjacent to said p-side waveguide, and n-doped cladding layer adjacent to said n-side waveguide; and
a polymer layer, said polymer layer forming sidewalls to said p-side waveguide, said n-side waveguide, and said absorption layer.

3. The photodiode of claim 2, wherein said polymer layer comprises Benzocyclobutene (“BCB”).

4. The photodiode of claim 1, wherein said undepleted absorption region, said depleted region, and said overlapping region have a thickness of approximately 1000 Å, 2000 Å, and 3000 Å, respectively.

5. The photodiode of claim 2, wherein said p-side waveguide and said n-side waveguide each have a thickness of approximately 1.1 μm, and wherein said p-doped cladding layer and said n-doped cladding layer have a thickness of approximately 1.5 μm and 1 μm, respectively.

6. A semiconductor photodiode comprising:
a p-side waveguide layer on said semiconductor for receiving positive charge carriers;
an n-side waveguide layer on said semiconductor for receiving negative charge carriers;
an absorption layer between said p-side waveguide and said n-side waveguide layers, said absorption layer being doped to have an absorption region and a depletion region that, when under bias, will overlap each other to form an undepleted absorption region, an overlapping region, and a depleted region; wherein the relative thickness of said undepleted absorption region, said depleted region, and said overlapping region substantially balance the transit time of said positive charge carriers and said negative charge carriers across said photodiode;
a p-doped cladding layer adjacent to said p-side waveguide;
an n-doped cladding layer adjacent to said n-side waveguide; and
a polymer layer, said polymer layer forming sidewalls to said p-side waveguide, said n-side waveguide, and said absorption layer.

7. The photodiode of claim 6, wherein said semiconductor comprises InP and said absorption layer comprises InGaAs, and wherein said polymer layer comprises Benzocyclobutene (“BCB”).

8. The photodiode of claim 6, wherein said undepleted absorption region, said depleted region, and said overlapping region have a thickness of approximately 1000 Å, 2000 Å, and 3000 Å respectively.

9. The photodiode of claim 6, wherein said p-side waveguide and said n-side waveguide each have a thickness of approximately 1.1 μm; and approximately wherein said p-doped cladding layer and said n-doped cladding layer have a thickness of 1.5 μm and 1 μm, respectively.

10. A semiconductor photodiode comprising:
a p-side waveguide layer on said semiconductor for receiving positive charge carriers;
an n-side waveguide layer on said semiconductor for receiving negative charge carriers;
an absorption layer between said p-side waveguide and said n-side waveguide layers, said absorption layer being doped to have an absorption region and a depletion region under bias that overlap each other to form an undepleted absorption region, an overlapping region, and a depleted region, said absorption region, said depleted region, and said overlapping region having a thickness of approximately, 1000 Å, 2000 Å, and 3000 Å, respectively.

11. The photodiode of claim 10, wherein said semiconductor comprises InP and said absorption layer comprises InGaAs, and said semiconductor further comprises:
a p-doped cladding layer adjacent to said p-side waveguide, an n-doped cladding layer adjacent to said n-side waveguide; and
a polymer layer, said polymer layer forming sidewalls to said p-side waveguide, said n-side waveguide, and said absorption layer.

12. The photodiode of claim 11, wherein said polymer layer comprises Benzocyclobutene (“BCB”).

13. The photodiode of claim 11, wherein said p-side waveguide and said n-side waveguide each have a thickness of approximately 1.1 μm, and said p-doped cladding layer and said n-doped cladding layer have a thickness of 1.5 μm and 1 μm, respectively.

14. A method of producing a semiconductor photodiode comprising the steps of:
forming a p-side waveguide layer on said semiconductor for receiving positive charge carriers;
forming an n-side waveguide layer on said semiconductor for receiving negative charge carriers;
forming an absorption layer between said p-side waveguide and said n-side waveguide layers, wherein said absorption layer is doped to have an absorption region and a depletion region that, when under bias, will overlap each other to form an undepleted absorption region, an overlapping region, and a depleted region to substantially balance the transit time of said positive charged carriers and negative charged carriers across said photodiode.

15. The method of claim 14, wherein said semiconductor comprises InP and said absorption layer comprises InGaAs and further comprising:
a p-doped cladding layer adjacent to said p-side waveguide, and n-doped cladding layer adjacent to said n-side waveguide; and
a polymer layer, said polymer layer forming sidewalls to said p-side waveguide, said n-side waveguide, and said absorption layer.

16. The method of claim 15, wherein said polymer layer comprises Benzocyclobutene (“BCB”).

17. The method of claim 14, wherein said undepleted absorption region, said depleted region, and said overlapping region have a thickness of approximately 1000 Å, 2000 Å, and 3000 Å, respectively.

18. The method of claim 14, wherein said p-side waveguide and said n-side waveguide each have a thickness of approximately 1.1 μm, and said p-doped cladding layer and said n-doped cladding layer have a thickness of 1.5 μm and 1 μm, respectively.
